(19) United States
(12) Patent Application Publication
(10) Pub. No.: US 2010/0020492 A1
(43) Pub. Date: Jan. 28, 2010

(54) HEAT-DISSIPATING DEVICE

(76) Inventor: Chin-Kuang LUO, Taichung City (TW)

Correspondence Address: FROMMER LAWRENCE & HAUG LLP, 745 FIFTH AVENUE, NEW YORK, NY, 10151, US

(21) Appl. No.: 12/251,888

(22) Filed: Oct. 15, 2008

(30) Foreign Application Priority Data
Jul. 24, 2008 (TW) 097128107

(51) Int. Cl. H05K 7/20

(52) U.S. Cl. 361/693; 361/690

(57) ABSTRACT

A heat-dissipating device includes a housing having a housing wall that defines an inner space and that is formed with first and second openings. A heat source is disposed inside the inner space. A heat-conductive set is in heat-communication with the heat source inside the inner space. A heat-exchange member is in heat-communication with fins of the heat-conductive set, and includes an inner tunnel that extends from the first opening to the second opening through the inner space so as to open to ambient air. The inner tunnel is free of fluid communication with the inner space, and ambient air can flow through the inner tunnel for heat exchange.

### CROSS-REFERENCE TO RELATED APPLICATION

This application claims priority of Taiwanese application no. 097128107, filed on Jul. 24, 2008.

### BACKGROUND OF THE INVENTION

1. Field of the Invention

The invention relates to a heat-dissipating device, more particularly to a heat-dissipating device that achieves a heat-dissipating effect with regard to a heat source in a closed space.

2. Description of the Related Art

In general, to achieve a heat-dissipating effect in an electronic apparatus comprising a housing, heat-dissipating holes are formed in said housing for heat dissipation, as disclosed in Taiwanese Patent Publication Number M329146. In another conventional embodiment, the housing is directly made of a heat-conductive metal material to enable heat exchange between the heat source and cool air in the ambience, as disclosed in Taiwanese Patent Number 557119.

However, since the aforementioned housing formed with holes for heat dissipation does not provide effects in waterproofing, moisture-proofing, dust-proofing, etc., electronic components in the electronic apparatus are prone to damage and the service lives thereof are short. Such a heat-dissipating mechanism is therefore not suitable for industrial or high-precision electronic apparatus. On the other hand, the aforementioned housing directly made of heat-conductive metal material provides effects in waterproofing, moisture-proofing, dust-proofing, etc. Nevertheless, since the electronic components are mounted in the housing, the heat-dissipating effect is poor and the manufacturing costs are relatively high. In particular, when the heat source is a plurality of high-power light-emitting diodes, accumulation of too much heat energy easily forms a storing space for the heat energy in the housing, which, in the long term, adversely affects functionalities of the electronic components and hence significantly reduces service lives of the electronic components.

### SUMMARY OF THE INVENTION

Therefore, the object of the present invention is to provide a heat-dissipating device that improves the heat-dissipating efficiency and provides waterproofing, moisture-proofing and dust-proofing effects.

Accordingly, a heat-dissipating device of the present invention comprises a housing, a heat source, a heat-conductive set and a heat-exchange member.

The housing includes a housing wall that defines an inner space and that has first and second openings.

The heat source, the heat-conductive set and the heat-exchange member are disposed inside the inner space. The heat-conductive set is in heat-communication with the heat source, and the heat-exchange member is in heat-communication with the heat-conductive set.

The heat-exchange member includes an inner tunnel that extends from the first opening to the second opening of the housing through the inner space so as to be open to ambient air. The inner tunnel is free of fluid communication with the inner space.

In a preferred embodiment, the heat-conductive set includes a heat-conductive component in heat-communication with the heat source, and a heat-dissipating component mounted between the heat-conductive component and the heat-exchange member.

The heat-conductive set further includes a base seat disposed between the heat source and the heat-conductive component. According to one embodiment, the heat-conductive component and the heat source are connected to opposite sides of the base seat.

The heat-conductive component is one of a solid-column, a U-shape plate, a hollow tube and a heat tube, and the heat-dissipating component includes a plurality of heat-dissipating parallel fins connected to the heat-conductive component.

According to one aspect of the invention, the heat-exchange member further includes a tubular member that confines the inner tunnel and that has opposite first and second ends sealed off from fluid communication with the inner space. The heat-conductive set includes a plurality of heat-dissipating parallel fins in contact with and transverse to the tubular member. Preferably, the tubular member penetrates the fin plates.

In a preferred embodiment, the heat-exchange member further includes a first sealing cap and a second sealing cap. The first and second sealing caps are sealingly connected between the first end of the tubular member and the first opening of the housing, and between the second end of the tubular member and the second opening of the housing, respectively.

Preferably, the first and second sealing caps are made of a rubber material.

According to an aspect of the invention, the housing includes a transparent portion in front of the heat source.

The effect of this invention is to generate a stack effect through implementation of the heat-exchange member, such that heat energy is transferred to the cool air of the ambience, thereby increasing the heat-dissipating efficiency.

### BRIEF DESCRIPTION OF THE DRAWINGS

Other features and advantages of the present invention will become apparent in the following detailed description of the preferred embodiment with reference to the accompanying drawings, of which:

FIG. 1 is a perspective view of the preferred embodiment of a heat-dissipating device according to the present invention;

FIG. 2 is a sectional view of the preferred embodiment; and

FIG. 3 is a bottom view of the preferred embodiment.

### DETAILED DESCRIPTION OF THE PREFERRED EMBODIMENT

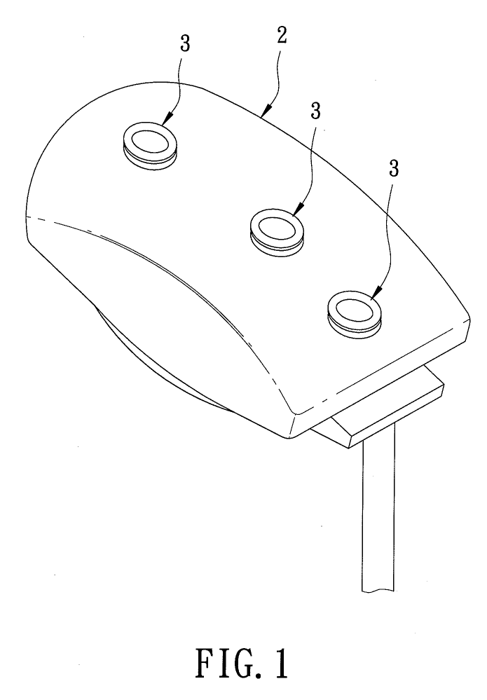

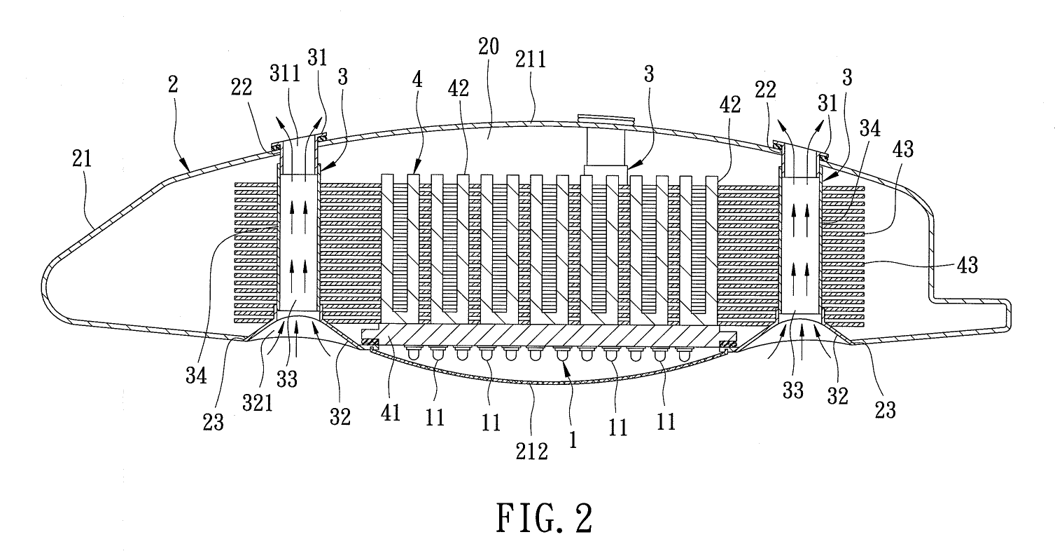

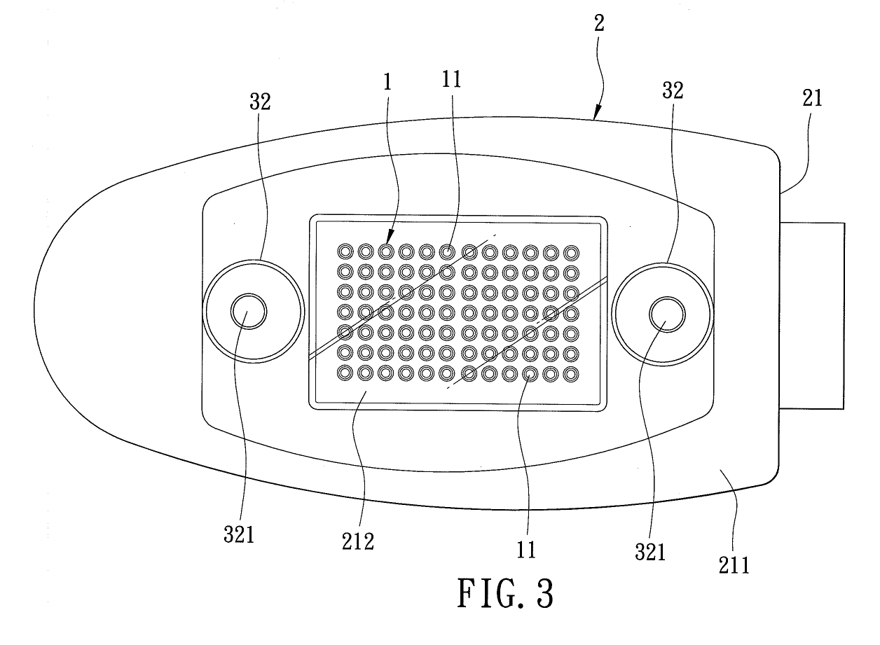

Referring to FIGS. 1 to 3, the preferred embodiment of a heat-dissipating device according to the present invention is shown to be adapted to a LED (light-emitting diode) lighting module 1 that comprises a plurality of LED units 11. The heat-dissipating device includes a housing 2, and a plurality of heat-exchange members 3 in heat communication with a heat-conductive set 4 which in turn is in heat communication with the LED lighting module.

The housing 2 includes a housing wall 21 that confines a closed inner space 20, and that is formed with a plurality of first openings 22 and a plurality of second openings 23 therethrough. The first openings 22 are provided in an upper portion of the housing wall 21, and the second openings 23 are provided in a lower portion of the housing wall 21.

The housing wall 21 includes a non-transparent portion 211 and a transparent portion 212. The transparent portion 212 is disposed in front of the light-emitting module 1.

Each of the heat-exchange members 3 includes a tubular member 34 surrounding an axis and confining the inner tunnel 33 that extends from one of the first openings 22 to one of the second openings 23, and a first sealing cap 31 and a second sealing cap 32 fixedly mounted on the tubular member 34. In this embodiment, the first and second sealing caps 31, 32 are made of a rubber material and have end orifices 311, 321 connecting the respective inner tunnels 33 to the ambience. The first and second sealing cap 31,32 sealingly connect the tubular members 34 to the housing wall 21 at the respective first and second openings 22, 23 so that the tubular members 34 are sealed off from fluid communication with the inner space 20. Therefore, the inner tunnels 33 communicate with the ambience through the end orifices 311, 321, but are free of fluid communication with the inner space 20.

The heat-conductive set 4 includes a base seat 41, a plurality of heat-conductive components 42, and a plurality of heat-dissipating components 43. The base seat 41 is disposed between the heat-conductive components 42 and the LED units 11. More precisely, the heat-conductive components 42 and the LED units 11 are connected to opposite sides of the base seat 41, and are enclosed in the inner space 20 of the housing 2.

In this embodiment, each of the heat-conductive components is a U-shaped plate. Alternatively, each of the heat-conductive components 42 can be one of a solid column, a hollow tube and a heat tube. The heat-dissipating components 43 are heat-dissipating parallel fins connected transversely to the heat-conductive components 42 and the tubular members 34.

Preferably, the heat-dissipating components or parallel fins 43 are in contact with and are penetrated by the tubular members 34 for improving heat exchange therebetween.

In operation, the preferred embodiment of a heat-dissipating device according to the present invention carries out the following steps:

Step 51: Heat energy is generated by the LED units 11 and conducted to the heat-conductive components 42 through the base seat 41.

Step 52: The heat-conductive components 42 conduct the heat energy to the inner space 20 of the housing 2 and transfers heat to the tubular members 34 of the heat-exchange members 3 via the heat-dissipating components 43.

Step 3: Each of the heat-exchange member 3 generates a stack effect according to the principle that hot air rises so that the hot air inside the inner tunnel 33 rises and escapes from the end orifice 311 of the top sealing cap 31 while cool air adjacent to the end orifice 321 of the bottom sealing cap 32 is drawn into the inner tunnel 33 through the end orifice 321. In such a manner, the tubular member 34 exchanges heat with the cool air of the ambience to achieve the heat-dissipating effect.

Aside from dissipating heat, the housing 2 also provides effects in waterproofing, moisture-proofing and dust-proofing. Since the material of the housing 2 need not be limited, the manufacturing costs thereof can be lowered, and the manufacturing process can be simplified, thereby enhancing practical use.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

What is claimed is:

1. A heat-dissipating device, comprising:
a housing including a housing wall that defines an inner space, and that has first and second openings;
a heat source disposed inside said inner space;
a heat-conductive set disposed inside said inner space and in heat-communication with said heat source; and
a heat-exchange member in heat-communication with said heat-conductive set, said heat-exchange member including an inner tunnel that extends from said first opening to said second opening of said housing through said inner space so as to open to ambient air.

2. The heat-dissipating device of claim 1, wherein said inner tunnel is free of fluid communication with said inner space.

3. The heat-dissipating device of claim 1, wherein said heat-conductive set includes:
a heat-conductive component in heat-communication with said heat source; and
a heat-dissipating component mounted between said heat-conductive component and said heat-exchange member.

4. The heat-dissipating device of claim 3, wherein said heat-conductive set further includes a base seat disposed between said heat source and said heat-conductive component.

5. The heat-dissipating device of claim 4, wherein said heat-conductive component and said heat source are connected to opposite sides of said base seat.

6. The heat-dissipating device of claim 3, wherein said heat-conductive component is one of a solid-column, a U-shaped plate, a hollow tube and a heat tube.

7. The heat-dissipating device of claim 5, wherein said heat-dissipating component includes a plurality of heat-dissipating parallel fins connected transversely to said heat-conductive component.

8. The heat-dissipating device of claim 7, wherein said heat-exchange member further includes a tubular member that confines said inner tunnel and that has opposite first and second ends sealed off from fluid communication with said inner space.

9. The heat-dissipating device of claim 8, wherein said heat-conductive set includes a plurality of heat-dissipating parallel fins in contact with and transverse to said tubular member.

10. The heat-dissipating device of claim 9, wherein said tubular member penetrates said fins.

11. The heat-dissipating device of claim 9, wherein said heat-exchange member further includes a first sealing cap and a second sealing cap, said first and second sealing caps being sealingly connected between said first end of said tubular member and said first opening of said housing, and between said second end of said tubular member and said second opening of said housing, respectively.

12. The heat-dissipating device of claim 11, wherein said first and second sealing caps are made of a rubber material.

13. The heat-dissipating device of claim 1, wherein said housing includes a transparent portion in front of said heat source.

14. The heat-dissipating device of claim 1, wherein said housing wall includes an upper portion and a lower portion below said upper portion, said first and second openings being disposed in said upper and lower portions, respectively.
